(19) United States
(12) Patent Application Publication
(10) Pub. No.: US 2025/0196692 A1
(43) Pub. Date: Jun. 19, 2025

(54) Method for Controlling Charging and Discharging of Rechargeable Battery

(71) Applicant: TOYOTA BATTERY Co., Ltd., Shizuoka (JP)

(72) Inventor: Yuya Inagaki, Okazaki-shi (JP)

(21) Appl. No.: 18/983,202

(22) Filed: Dec. 16, 2024

(30) Foreign Application Priority Data
Dec. 19, 2023 (JP) 2023-214296

(51) Int. Cl. B60L 53/62; B60L 58/12; G01R 31/388

(52) U.S. Cl. CPC B60L 53/62; B60L 58/12; G01R 31/388

(57) ABSTRACT

A method for controlling charging and discharging of a rechargeable battery with a controller includes acquiring a measured current, a measured voltage, and a measured temperature; estimating an estimated voltage based on the measured current and the measured temperature; collecting samples each indicating a difference between the measured voltage and the estimated voltage; classifying the samples into an upper limit side determination sample and a lower limit side determination sample with reference to a reference value; calculating an upper limit error based on at least a predetermined quantity of the upper limit side determination sample, and calculating a lower limit error based on at least a predetermined quantity of the lower limit side determination sample; and resetting an upper limit of a usable SOC range in accordance with the upper limit error, and resetting a lower limit of the usable SOC range in accordance with the lower limit error.

### CROSS-REFERENCE TO RELATED APPLICATIONS

This application is based upon and claims the benefit of priority from Japanese Patent Application No. 2023-214296, filed on Dec. 19, 2023, the entire contents of which are incorporated herein by reference.

### BACKGROUND

### 1. Field

The following description relates to a method for controlling charging and discharging of a rechargeable battery. More specifically, the description relates to a method for controlling charging and discharging of a rechargeable battery such that a usable range of the state of charge (SOC) is controlled in accordance with an SOC estimation error. The control allows for charging and discharging of the rechargeable battery that is safe and efficient.

### 2. Description of Related Art

In rechargeable batteries, particularly, in rechargeable batteries mounted on battery electric vehicles or hybrid electric vehicles as driving power supply, large currents are discharged during sudden acceleration and recharged by regenerative braking or quick charging, for example. In order to avoid overcharging and overdischarging, a usable range of the SOC is controlled. For example, charging and discharging is controlled so that the SOC continuously remains in a range between a lower limit value set at 20% and an upper limit value set at 80%.

Japanese Laid-Open Patent Publication No. 2011-041436 describes an example of a technique that controls a charging/discharging rate in accordance with the SOC. However, even when an erroneous calculation of the SOC changes a suitable SOC range, the technique of Patent Literature 1 does not correct the usable range of the SOC.

In this respect, the following technique has been developed to control charging and discharging of the battery more safely and efficiently.

Japanese Laid-Open Patent Publication No. 2015-197428 describes an example of a technique that obtains the SOC from a current integrated value as a true value, and calculates an SOC estimation error with respect to the true value. Then, upper and lower limits of the SOC are corrected accordingly. Such a technique allows for more appropriate control.

Japanese Laid-Open Patent Publication No. 2022-502815 describes a technique that acquires a parameter of a battery model using a neural network. Then, the parameter of the battery model is repeatedly updated in accordance with a difference between an output value of the battery model that reflects the acquired parameter and an actual measurement value. This constructs a battery model optimized for a battery cell such that charging of the battery cell can be controlled based on the optimized battery model. Such a technique allows for more appropriate control.

Nonetheless, the technique described in Japanese Laid-Open Patent Publication No. 2015-197428 requires a relatively large amount of time to obtain the estimation error since the current integrated value is used as the true value of the SOC estimation. Further, measurement of the current may also be erroneous such that the current integrated value is likely to be affected by accumulation of such errors over an extended period of estimation.

Moreover, the correction method described in Japanese Laid-Open Patent Publication No. 2022-502815 updates the battery model each time the difference between the output value and the actual measurement value is obtained. Thus, the control on the SOC range cannot be separated from the battery model. Also, when the battery is initially used, the estimation error cannot be taken into consideration since the model has not been corrected.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method is for controlling charging and discharging of a rechargeable battery with a controller. The method includes acquiring a measured current A_{M} (A), a measured voltage V_{M} (V), and a measured temperature T_{M} (° C.) through measurement of the rechargeable battery; estimating an estimated voltage V_{E} (V) based on the measured current A_{M} (A) and the measured temperature T_{M} (° C.); collecting samples each indicating a difference ΔV (V) between the measured voltage V_{M} (V) and the estimated voltage E_{E} (V) for calculating an SOC estimation error E (%), the samples being collected when a current I is flowing through the rechargeable battery under a certain condition; classifying the collected samples into an upper limit side determination sample SP_{H} and a lower limit side determination sample SP_{L} with reference to a reference value S (%) set at a preset normal SOC center; calculating an upper limit error E_{H} (%), which is an estimation error E with respect to an upper limit L_{H} of a usable SOC range S_{U}, based on at least a predetermined quantity of the collected upper limit side determination sample SP_{H}, and calculating a lower limit error E_{L} (%), which is the estimation error E_{L} with respect to a lower limit L_{L} of the usable SOC range S_{U}, based on at least a predetermined quantity of the collected lower limit side determination sample SP_{L}; and resetting the upper limit L_{H} of the usable SOC range S_{U} in accordance with the upper limit error E_{H} (%), and resetting the lower limit L_{L} of the usable SOC range S_{U} in accordance with the lower limit error E_{L} to control the usable SOC range S_{U} of the rechargeable battery.

The above method may further include executing a guard process that optimizes the usable SOC range S_{U} based on the reset upper limit L_{H} and the reset lower limit L_{L} of the reset usable SOC range S_{U}.

In the above method, the executing a guard process may include controlling resetting of the upper limit L_{H} and the lower limit L_{L} so that the usable SOC range S_{U} is greater than or equal to 20% based on the upper limit L_{H} and the lower limit L_{L}.

In the above method, the executing a guard process may include setting the upper limit L_{H}, which is reset in accordance with the upper limit error E_{H}, in a range of a minimum difference ΔMin to a maximum difference ΔMax of the upper limit error E_{H}, and setting the lower limit L_{L}, which is reset in accordance with the lower limit error E_{L}, in a range of a minimum difference ΔMin to a maximum difference ΔMax of the lower limit error E_{L}.

In the above method, the estimating an estimated voltage V_{E} (V) may include estimating a voltage V_{E} (V), which corresponds to a closed circuit voltage of the rechargeable battery, as the estimated voltage using a preset battery model of the rechargeable battery.

The above method may further include correcting the battery model through comparison of the measured voltage V_{M} (V) and the estimated voltage V_{E} (V).

In the above method, the correcting the battery model may be performed when the difference ΔV (V) between the measured voltage V_{M} (V) and the estimated voltage V_{E} (V) becomes greater than or equal to a threshold value Th.

In the above method, the classifying the collected samples may include setting the reference value S to a value in a range of SOC 40% to SOC 60%, inclusive. The reference value S may be set at the preset normal SOC center for classifying the collected samples into the upper limit side determination sample and the lower limit side determination sample.

In the above method, when the SOC estimation error is represented by E (%), a quantity of collected samples is represented by N, a number of sample collections executed is represented by k, the measured voltage is represented by V_{M} (V), the estimated voltage is represented by V_{E} (V), and a voltage corresponding to 1% of SOC of the rechargeable battery is represented by V₁ (V), the calculating an upper limit error E_{H} (%) and a lower limit error E_{L} (%) may include calculating the estimation error E (%) using Equation 1.

$$\begin{matrix}Expression 1 & \\ Estimation Error E = \frac{1}{N} {\sum }_{k = 1}^{N} ( \frac{\vert {V}_{M} - {V}_{E} \vert}{{V}_{1}} ) & Equation 1\end{matrix}$$

In the above method, the rechargeable battery may serve as a driving power supply for a vehicle. The controller may be mounted on the vehicle.

In the above method, the rechargeable battery may be a lithium-ion rechargeable battery.

Other features and aspects will be apparent from the following detailed description, the drawings, and the claims.

### BRIEF DESCRIPTION OF THE DRAWINGS

FIG. 1 is a diagram illustrating an SOC control in accordance with the present embodiment.

FIG. 2 is a diagram showing an equivalent circuit of a battery model for a lithium-ion rechargeable battery in accordance with the present embodiment.

FIG. 3 is a perspective view showing an external appearance of the lithium-ion rechargeable battery in accordance with the present embodiment.

FIG. 4 is a schematic diagram showing an electrode body of the lithium-ion rechargeable battery in accordance with the present embodiment.

FIG. 5 is a block diagram showing an example of the configuration of a vehicle to which the lithium-ion rechargeable battery is applied.

FIG. 6 is a block diagram showing a detailed configuration of memory in an ECU of a fully-charged battery capacity estimator in accordance with the present embodiment.

FIG. 7 is a flowchart illustrating a procedure of a method for controlling charging and discharging of the lithium-ion rechargeable battery in accordance with the present embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### Overview of the Present Embodiment

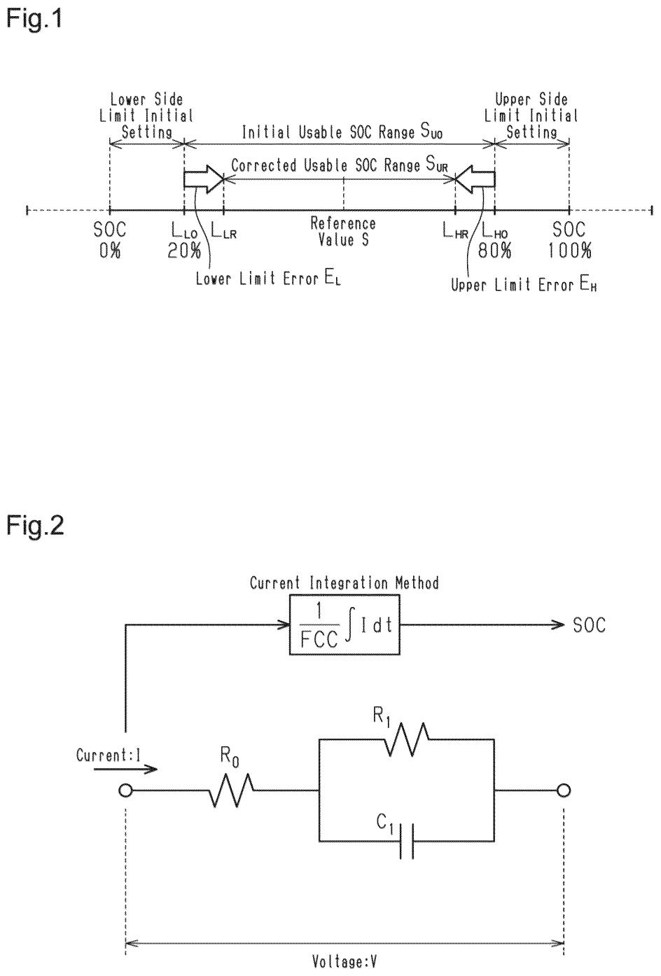

A method for controlling charging and discharging of a rechargeable battery in accordance with the present disclosure will now be described using an example of a method for controlling charging and discharging a lithium-ion rechargeable battery 1 with reference to FIGS. 1 to 7.

### Principles of the Present Disclosure

The method for controlling charging and discharging of the lithium-ion rechargeable battery 1 of the present embodiment corrects a usable range of the SOC in accordance with an SOC estimation error without requiring complicated procedures so that charging and discharging are controlled safely and efficiently. As described in Background section, the technique of Japanese Laid-Open Patent Publication No. 2015-197428 requires a relatively large amount of time to obtain the estimation error since the current integrated value is used as the true value of the SOC estimation. Further, measurement of the current may also be erroneous such that the current integrated value is likely to be affected by accumulation of such errors over an extended period of estimation. Moreover, the correction method described in Japanese Laid-Open Patent Publication No. 2022-502815 updates the battery model each time the difference between the output value and the actual measurement value is obtained. Thus, the control on the SOC range cannot be separated from the battery model. Also, when the battery is initially used, the estimation error cannot be taken into consideration since the model has not been corrected.

In these respects, the method for controlling charging and discharging of the lithium-ion rechargeable battery 1 in accordance with the present embodiment estimates the SOC using a voltage so that the measurement error and the measurement time are reduced compared to when the SOC is estimated from a current integrated value. This allow for quick detection of SOC errors in real time. In addition, the battery model is corrected when necessary so that the degree of accuracy in estimating the SOC can be increased by using the corrected model. In this manner, the SOC error is readily detected at a relatively high degree of accuracy. Thus, even when a battery has a use history, an appropriate usable range of the SOC may be set. This limits deterioration of the battery and enhances the sufficient performance of the battery.

### SOC (%) Estimation of the Present Embodiment

FIG. 1 is a diagram illustrating an SOC control in accordance with the present embodiment. In the lithium-ion rechargeable battery 1 of the present embodiment, the SOC is set from 0% to 100% at an initial stage, and a battery model of such a lithium-ion rechargeable battery 1 is prepared.

FIG. 2 is a diagram showing an equivalent circuit of the battery model for the lithium-ion rechargeable battery 1 in accordance with the present embodiment. As shown in FIG. 2, the lithium-ion rechargeable battery 1 may indicate the equivalent circuit by a register (resistance) R₀ and a parallel circuit of a register R₁ and a capacitor C₁ connected in series thereto. Such an equivalent circuit allows for determination of the values of register R₀, register R₁, and capacitor C₁ through, for example, a complex AC impedance measurement. Then, a combined resistance of the entire equivalent circuit may be obtained. An actual change in the state of the lithium-ion rechargeable battery 1 may be affected by various elements. For example, such elements include an increase in the internal resistance due to coating formation such as a solid electrolyte interphase (SEI) on the anode, decomposition of a non-aqueous electrolyte solution, self-discharge caused by a micro-short circuit, temporary unevenness of ions, or the like. However, these elements may be simplified to facilitate an SOC estimation, and thus the equivalent circuit may be indicated by the registers (resistances) R₀ and R₁ and the capacitor (capacitance) C₁. Such a battery model may be used to obtain an estimated voltage V_{E} (V) based on a measured current A_{M} (A) and a measured temperature T_{M} (° C.). The temperature may change the internal resistance. Thus, a correction should be performed in accordance with the temperature. Further, the battery model is not invariant. Thus, a correction should be performed in accordance with deterioration.

In the battery model configured as described above, the SOC (%) may be estimated based on an open circuit voltage OCV. However, in the present embodiment, a voltage is measured between two terminals in a state in which the battery is connected to a device and a current is flowing through the battery. Thus, a closed circuit voltage CCV is measured. Due to the internal resistance of the battery, the closed circuit voltage has a smaller value than the open circuit voltage, and the closed circuit voltage decreases as the current flowing increases. Accordingly, a lithium-ion rechargeable battery 1 of the same type is measured in advance to obtain the correspondence between the voltage (V) and the SOC (%). A conversion table prepared based on such a relationship allows the SOC (%) to be immediately estimated from a measured voltage V_{M} (V).

In contrast, the current integration method estimates the SOC (%) of the lithium-ion rechargeable battery 1 by integrating currents I (A). Specifically, the present SOC (%) may be estimated from a ratio of an integrated value of ∫Idt (Wh) to a fully charge capacity FCC.

In the present embodiment, the battery model described above is used to estimate the SOC (%).

### Usable SOC Range S_{U}

As shown in FIG. 1, an upper limit L_{H0} (%) is determined for the SOC (%) of the unused reference battery. The upper limit L_{H0} (%) is an upper limit in an initial setting that is normally used. In the present embodiment, for example, the upper limit L_{H0} (%) is set to 80%. This serves as a margin for avoiding overcharging even when, for example, regenerative braking is performed on a long downhill slope or the like. Further, a lower limit L_{L0} (%) is determined. The lower limit L_{L0} (%) is a lower limit of an initial setting that is normally used. In the present embodiment, for example, the lower limit L_{L0} (%) is set to 20%. This serves a margin for avoiding overdischarging even when, for example, a large current is discharged as the driving electric power on a long uphill slope or the like.

The range of such upper limit L_{H0} and lower limit L_{L0} corresponds to a usable SOC range S_{U} (%). In the present embodiment, the usable SOC range S_{U} (%) is a range of 20% to 80%, inclusive.

However, for example, when the lithium-ion rechargeable battery 1 has an unknown use history, deterioration may lead to a decrease in the battery capacity or an increase in the internal resistance. In such cases, even if the measured voltage V_{M} (V) or the measured current A_{M} (W) are the same, the SOC (%) estimated based on these values may be erroneous.

### Information Acquisition Step/Battery Voltage Estimation Step

In the present embodiment, the SOC is estimated based on the battery model. The measured voltage V_{M} (V) of the lithium-ion rechargeable battery 1 is actually obtained. Further, the estimated voltage V_{E} (V) based on the battery model is simultaneously obtained. Then, a difference ΔV (V) between the measured voltage V_{M} (V) and the estimated voltage V_{E} (V) is calculated. It can be understood that the difference ΔV (V) is a result of deterioration of the battery from the state corresponding to the initial stage of the battery model. Accordingly, an estimation error E (%) of the SOC (%) is obtained based on the difference ΔV (V).

### Sample Collection Step/Sample Classification Step

Samples are used for calculating the estimation error E (%). Specifically, the samples each indicate the difference ΔV (V) between the measured voltage V_{M} (V) and the estimated voltage V_{E} (V). The SOC error is estimated based on the difference ΔV (V) between the measured voltage V_{M} (V) and the estimated voltage V_{E} (V). In a sample collection step, multiple samples for calculating the SOC estimation error E (%) are collected when the current I (measured current A_{M}) is flowing through the lithium-ion rechargeable battery 1 under a certain condition. The certain condition is, for example, a condition in that electric power (W) measured as the measured current A_{M} is greater than or equal to 1000 W over a duration of five seconds. Accordingly, the samples serve as significant datasets in the estimation of the SOC error.

Further, the collected samples are classified with reference to a reference value S set at a center of a preset normal SOC (preset normal SOC center). The reference value S is set in a range of SOC 40% to SOC 60%, inclusive. This is because the behavior of the battery may change in a high-SOC range and a low-SOC range outside the approximate SOC range of 40% to 60%. In the present embodiment, the reference value S is set to 50%. For example, when a sample indicates the measured voltage V_{M} (V) of 4.000 V, the SOC is estimated to be greater than or equal to 50%, which is greater than the reference value S. Thus, the subject sample is classified as an upper limit side determination sample SP_{H}. When a sample indicates the measured voltage V_{M} (V) of 3.500 V, the SOC is estimated to be less than or equal to 50%, which is less than the reference value S. Thus, the subject sample is classified as a lower limit side determination sample SP_{L}.

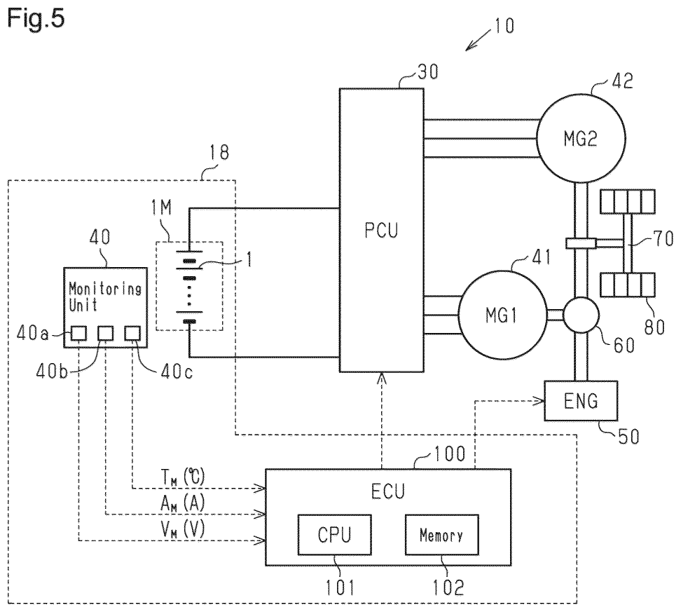

In this manner, multiple samples are collected and classified into the upper limit side determination sample SP_{H} and the lower limit side determination sample SP_{L}. These samples are accumulated in memory 102 (FIG. 5) of a controller 18. An SOC estimation error calculation step calculates an upper limit error E_{H} (%) based on at least a predetermined quantity of the collected upper limit side determination samples Sam_{H}, and calculates a lower limit error E_{L} (%) based on at least a predetermined quantity of the collected lower limit side determination samples Sam_{L}. In other words, the upper limit error E_{H} (%) corresponds to the estimation error E (%) with respect to the upper limit L_{H}, and the lower limit error E_{L} (%) corresponds to the estimation error E (%) with respect to the lower limit L_{L}. In the description hereafter, the upper limit error E_{H} (%) and the lower limit error E_{L} (%) may be collectively referred to as the estimation error E (%).

### SOC Estimation Error Calculation Step

The SOC estimation error E (%) of the present embodiment is calculated using the equation below. The estimation error E (%) is calculated using the upper limit side determination sample SP_{H} and the lower limit side determination sample SP_{L}, separately. When a predetermined quantity of upper limit side determination samples SP_{H} and a predetermined quantity of lower limit side determination samples SP_{L} are collected (e.g., ten samples each in the present embodiment), the estimation error E (%), or the upper limit error E_{H} and the lower limit error E_{L} (%), is calculated using each of the collected upper limit side determination samples SP_{H} and each of the collected lower limit side determination samples SP_{L}.

When the estimation error is represented by E (%), the quantity of collected samples is represented by N, the number of sample collections executed is represented by k, the measured voltage is represented by V_{M} (V), the estimated voltage is represented by V_{E} (V), and a voltage corresponding to 1% of the SOC of the rechargeable battery is represented by V₁ (V), the estimation error E (%) is obtained using Equation 1.

$$\begin{matrix}Expression 1 & \\ Estimation Error E = \frac{1}{N} {\sum }_{k = 1}^{N} ( \frac{\vert {V}_{M} - {V}_{E} \vert}{{V}_{1}} ) & Equation 1\end{matrix}$$

The voltage V₁ (V) corresponding to SOC 1% of the rechargeable battery may be calculated as follows. An example assumes that a voltage at SOC 100% is 4.2 V, and a voltage at SOC 0% is 3.0 V. In this case, the voltage difference V₁ (V) corresponding to SOC 100% is 4.2−3.0=1.2 V. The voltage V₁(V) corresponding to SOC 1% is obtained by dividing the value by 100, which is approximately 0.012 V (12 mV).

Next, an example assumes that the measured voltage V_{M} (V) obtained from the upper limit side determination sample SP_{H} is 4.000 V. Further, the calculated estimated voltage V_{E} (V) is 4.100 V.

In this case, V_{M}−V_{E}=4.000−4.100=−0.100 V. The absolute value |V_{M}−V_{E}| of (V_{M}−V_{E}) is 0.100. When the obtained |V_{M}−V_{E}| is divided by V₁, 0.100/0.012=8.3. This value expressed as a percentage is 8.3%.

In the present embodiment, the estimation error E (%) is repeatedly obtained with each of ten upper limit side determination samples SP_{H}, and then the arithmetic mean of the ten values is calculated as the upper limit error E_{H} (%). An example assumes that the upper limit error E_{H} (%) is 8.3%.

### SOC Upper and Lower Limits Resetting Step

An SOC upper and lower limits resetting step resets the upper limit L_{H} of the usable SOC range in accordance with the upper limit error E_{H} (%), and resets the lower limit L_{L} of the usable SOC range in accordance with the lower limit error E_{L}.

As shown in FIG. 1, the upper limit L_{H0} (%) of the initial setting is 80%. If charging and discharging are controlled with the upper limit L_{H0} (%) of the initial setting at SOC=80%, deterioration of the battery may cause, for example, a reduction in the battery capacity (Ah). Thus, the actual upper limit L_{H0} (%) may become a higher SOC (%).

In this respect, the upper limit L_{H0} (%) of the initial setting is changed to a corrected upper limit L_{HR} (%) based on the upper limit error E_{H} (%) calculated in the SOC estimation error calculation step. In the same manner, the initial lower limit L_{L0} (%) of the initial setting is changed to a corrected lower limit L_{LR} (%) based on the lower limit error E_{L} (%) calculated in the SOC estimation error calculation step. An example assumes that the lower limit error E_{L} is 8.3%. This changes the initial usable SOC range S_{U0} (%) to a corrected usable SOC range S_{U1} (%). In the present embodiment, the initial usable SOC range S_{U0}=80−20=60% is changed to the corrected usable SOC range S_{U1} (%)=(80−8.3)−(20+8.3)=43.4%.

### Upper and Lower Limits Guarding Step

An upper and lower limits guarding step executes a guard process. The upper limit L_{H} and the lower limit L_{L} of the usable SOC range are reset by the SOC upper and lower limits resetting step based on the estimation error E (%). In this case, the usable SOC range S_{U} is optimized based on the upper limit L_{H} of the usable SOC range and the lower limit L_{L} of the usable SOC range. The optimization is a process performed to ensure the usable SOC range S_{U1} (%). This is because when the estimation error E (%) is excessively large, the corrected usable SOC range S_{U1} (%) that is actually usable may be significantly narrowed.

In the present embodiment, the upper limit L_{H} used in the guard process is obtained in accordance with Equation 2 “upper limit L_{H1}=L_{H0}−(minimum difference ΔMin≤upper limit error E_{H1}≤maximum difference ΔMax)”. In the present embodiment, the lower limit L_{L} used in the guard process is obtained in accordance with Equation 3 “lower limit L_{L1}=L_{L0}+(minimum difference ΔMin≤lower limit error E_{L}≤maximum difference ΔMax)”.

The portion (minimum difference ΔMin≤upper limit error E_{H}≤maximum difference ΔMax) means that the upper limit error E_{H} is limited to the range “minimum difference ΔMin≤upper limit error E_{H}≤maximum difference ΔMax”.

An example assumes that the minimum difference ΔMin is 0%, and the maximum difference ΔMax is 20%.

In this case, if the upper limit error E_{H} (%) is 8.3% as described above, the value is within the range “the minimum difference ΔMin≤upper limit error E_{H}≤maximum difference ΔMax”. Thus, the guard process is not executed.

An example assumes that the measured voltage V_{M} (V) obtained from the upper limit side determination sample SP_{H} is 4.011 V. Further, the calculated estimated voltage V_{E} (V) is 4.001 V. In this case, the upper limit error E_{H} obtained by Equation 1 is 83%. When the upper limit error E_{H}=83% is applied to Equation 2, the upper limit error E_{H} is greater than the maximum difference ΔMax of 20%. Thus, the upper limit error E_{H} is limited to 20%.

Therefore, when Equation 2 “upper limit L_{H}1=L_{H0}−(minimum difference ΔMin≤upper limit error E_{H}≤maximum difference ΔMax)” is applied, “upper limit L_{H1}=L_{H0}−(minimum difference ΔMin≤upper limit error E_{H}≤maximum difference ΔMax)”=80−(20)=60. Thus, the upper limit L_{H1} will not become less than 60%.

In the same manner, Equation 3 “lower limit L_{L1}=L_{L0}+(minimum difference ΔMin≤lower limit error E_{L}≤maximum difference ΔMax)” is applied to the lower limit L_{L1}. In this case, an example also assumes that the minimum difference ΔMin is 0%, and the maximum difference ΔMax is 20%.

An example assumes that the measured voltage V_{M} (V) obtained from the lower limit side determination sample SP_{L} is 3.510 V. Further, the calculated estimated voltage V_{E} (V) is 3.500 V. In this case, the lower limit error E_{L} obtained by Equation 1 is 83%. When the lower limit error E_{L}=83% is applied to Equation 3, the lower limit error E_{L} is greater than the maximum difference ΔMax=20%. Thus, the lower limit error E_{L} is limited to 20%.

Therefore, when Equation 3 “lower limit L_{L1}=L_{L0}+(minimum difference ΔMin≤lower limit error E_{L}≤maximum difference ΔMax)” is applied, “lower limit L_{L1}=L_{L0}+(minimum difference ΔMin≤lower limit error E_{L}≤maximum difference ΔMax)”=20+(20)=40. Thus, the lower limit L_{L1} will not exceed 40%.

### Optimization of Corrected Usable SOC Range S_{U1}

The upper and lower limits guarding step sets the upper limit L_{H} (%) in accordance with the upper limit error E_{H} (%) in a range of the minimum difference ΔMin to the maximum difference ΔMax of the upper limit error E_{H}. Further, the lower limit L_{L} (%) is set in accordance with the lower limit error E_{L} (%) in a range of the minimum difference ΔMin to the maximum difference ΔMax of the lower limit error E_{L}. In this case, Equation 4 “corrected usable SOC range S_{U1}=initially set usable SOC range S_{U0}−(maximum difference ΔMax of upper limit error E_{H}+maximum difference ΔMax of lower limit error E_{L})” is applied. An example assumes that the usable SOC range S_{U} is initially set to 60%, and the usable SOC range S_{U} should be at least 20% in an actual vehicle. In this case, Equation 4 is “corrected usable SOC range S_{U1}=initially set usable SOC range S_{U0}−(maximum difference ΔMax of upper limit error E_{H}+maximum difference ΔMax of lower limit error E_{L})≥20%”. This sets the corrected usable SOC range S_{U1} (%) to 20% or greater. In other words, when “(maximum difference ΔMax of upper limit error E_{H}+maximum difference ΔMax of lower limit error E_{L})≤40%” is satisfied, it is ensured that the corrected usable SOC range S_{U1} is 20% or greater.

### Battery Model Correction Step

In the present embodiment, a battery model correction step is performed when the difference ΔV (V) between the measured voltage V_{M} (V) and the estimated voltage V_{E} (V) becomes greater than or equal to a threshold value Th. The battery model correction step reexamines the registers R₀ and R₁, the capacitor C₁, or the like of the battery model shown in FIG. 2, and specifies the threshold value Th of the difference ΔV (V) between the measured voltage V_{M} (V) and the estimated voltage V_{E} with the voltage value (V). Alternatively, the threshold value Th may be specified based on a ratio of the measured voltage V_{M} (V) and the estimated voltage V_{E}.

The battery model correction step may be performed when a different condition is satisfied, for example, the battery is used over a certain amount of time.

### Structure of the Present Embodiment

### Structure of Lithium-Ion Rechargeable Battery 1

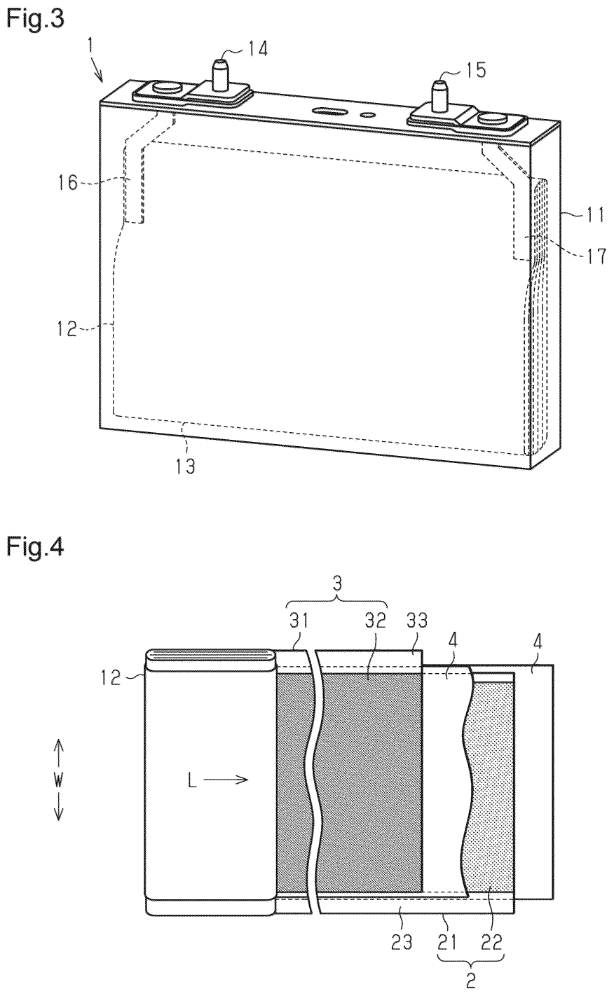

FIG. 3 is a perspective view schematically showing an external appearance of the lithium-ion rechargeable battery 1 in accordance with the present embodiment. The structure of the lithium-ion rechargeable battery 1 in accordance with the present embodiment, which is an example of the present disclosure, will now be described.

The lithium-ion rechargeable battery 1 shown in FIG. 3 is a battery cell that forms part of a battery module 1M (refer to FIG. 5). The lithium-ion rechargeable battery 1, which is a battery cell, includes a box-shaped battery case 11 having an opening in the upper side. The battery case 11 accommodates an electrode body 12. The battery case 11 is filled with a non-aqueous electrolyte solution 13 injected through a liquid injection hole. The battery case 11 is formed of a metal such as an aluminum alloy, and forms a sealed battery container by attaching a lid. Further, the lithium-ion rechargeable battery 1 includes a cathode external terminal 14 and an anode external terminal 15 used for charging and discharging the lithium-ion rechargeable battery 1. The cathode external terminal 14 is electrically connected through the lid to a cathode current collector terminal 16 inside the battery case 11. The anode external terminal 15 is electrically connected through the lid to an anode current collector terminal 17 inside the battery case 11. The cathode current collector terminal 16 is electrically connected to a cathode current collection portion 33 (refer to FIG. 4) of the electrode body 12. The anode current collector terminal 17 is electrically connected to an anode current collection portion 23 (refer to FIG. 4) of the electrode body 12.

### Electrode Body 12

FIG. 4 is a schematic diagram showing the electrode body 12 in an unrolled state. In the electrode body 12, an anode plate 2, a cathode plate 3, and a separator 4 disposed in between are stacked. The stack of the anode plate 2, the cathode plate 3, and the separator 4 is rolled and flattened. The anode plate 2 includes an anode current collector 21, which is formed by a copper foil serving as a substrate, and an anode mixture layer 22 formed on the anode current collector 21. The anode current collection portion 23 is arranged at one end of the electrode body 12 in a widthwise direction W (rolling axial direction) that is orthogonal to a direction in which the stack is rolled (rolling direction L). The anode current collection portion 23 corresponds to where the anode mixture layer 22 is not formed such that the anode current collector 21 is exposed.

The cathode plate 3 includes a cathode current collector 31, which is formed by an aluminum foil serving as a substrate, and a cathode mixture layer 32 formed on the cathode current collector 31. As shown in FIG. 4, the cathode current collection portion 33 is arranged at the other end (opposite to anode current collection portion 23) of the electrode body 12 in the widthwise direction W (rolling axial direction) that is orthogonal to the direction in which the stack is rolled (rolling direction L). The cathode current collection portion 33 corresponds to where the cathode mixture layer 32 is not formed such that the metal of the cathode current collector 31 is exposed.

### Stack Structure of Electrode Body 12

As shown in FIG. 4, the basic structure of the electrode body 12 of the lithium-ion rechargeable battery 1 includes the anode plate 2, the cathode plate 3, and the separator 4.

The anode plate 2 includes the anode mixture layer 22 arranged on two opposite surfaces of the anode current collector 21, which serves as the anode substrate. An end of the anode current collector 21 at one side corresponds to the anode current collection portion 23 where the metal is exposed.

The cathode plate 3 includes the cathode mixture layer 32 arranged on two opposite surfaces of the cathode current collector 31, which serves as the cathode substrate. An end of the cathode current collector 31 at the other side corresponds to the cathode current collection portion 33 where the metal is exposed.

The stack of the anode plate 2 and the cathode plate 3 is formed with the separators 4 disposed in between. The stack is rolled about the rolling axis in a longitudinal direction as shown in FIG. 4, and then flattened to form the roll-type electrode body 12 such as that shown in FIG. 3.

### Non-Aqueous Electrolyte Solution 13

As shown in FIG. 3, in the lithium-ion rechargeable battery 1 of the present embodiment, the electrode body 12 is impregnated with the non-aqueous electrolyte solution 13. The non-aqueous electrolyte solution 13 is a composition in which a lithium salt is dissolved in an organic solvent. The lithium salt may be LiClO₄, LiPF₆, LiAsF₆, LiBF₄, LiSO₃CF₃ or the like. Examples of the organic solvent include a cyclic carbonate (e.g., ethylene carbonate, propylene carbonate, butylene carbonate, trifluoropropylene carbonate, or the like), a chain carbonate (e.g., diethyl carbonate, dimethyl carbonate, ethyl methyl carbonate, dipropyl carbonate, or the like), an ether compound (e.g., tetrahydrofuran, 2-methyltetrahydrofuran, dimethoxyethane, or the like), a sulfur compound (e.g., ethyl methyl sulfone, butane sultone, or the like), a phosphorus compound (e.g., triethyl phosphate, trioctyl phosphate, or the like), or the like. One of these compounds or a mixture of more than one of these compounds may be used as the non-aqueous electrolyte solution 13. The composition of the non-aqueous electrolyte solution 13 is not limited to those described above.

### Components of Electrode Body 12

The components of the electrode body 12, namely, the anode plate 2, the cathode plate 3, and the separator 4, will now be described.

### Anode Plate 2

As shown in FIG. 4, the anode plate 2 is obtained by forming the anode mixture layer 22 on the two opposite surfaces of the anode current collector 21, which serves as the anode substrate. In the anode mixture layer 22, an anode mixture paste is applied to the anode current collector 21. Then, a drying step, a pressing step, and a cutting step are performed to complete the anode plate 2.

### Anode Current Collector 21

In the present embodiment, the anode current collector 21 is formed by a Cu foil. The anode current collector 21 serves as a base for the anode mixture layer 22 and has the functionality of a current collecting member that collects electricity from the anode mixture layer 22. One end of the anode current collector 21 includes the anode current collection portion 23 where the anode mixture layer 22 is not formed such that the metal surface is exposed. Accordingly, anode active material particles are electrically connected to the anode external terminal 15 via the anode current collector 21, the anode current collection portion 23, and the anode current collector terminal 17.

### Anode Mixture Layer 22

In the present embodiment, the anode active material is a powder carbon material formed from graphite having a layered structure or the like. The anode active material is capable of storing and releasing lithium ions Lit.

### Cathode Plate 3

As shown in FIG. 4, the cathode plate 3 includes the cathode current collector 31, which serves as the cathode substrate, and the cathode mixture layer 32 applied to the cathode current collector 31. In the cathode mixture layer 32, a cathode mixture paste is applied to the cathode current collector 31. Then, a drying step, a pressing step, and a cutting step are performed to complete the cathode plate 3.

### Cathode Current Collector 31

The cathode plate 3 has a structure in which the cathode mixture layer 32 is formed on the two opposite surfaces of the cathode current collector 31, which serves as the cathode substrate. In the present embodiment, the cathode current collector 31 is formed by an Al foil. The cathode current collector 31 serves as a base for the cathode mixture layer 32 and has the functionality of a current collecting member that collects electricity from the cathode mixture layer 32.

An Al foil is described as an example of the cathode substrate that forms the cathode current collector 31. The cathode substrate may be formed from, for example, a conductive material including a metal that has satisfactory electric conduction. A material having satisfactory electric conduction may be, for example, an Al foil or a material including an Al alloy. The cathode current collector 31 is not limited to the structure described above.

### Cathode Mixture Layer 32

The cathode mixture layer 32 is formed by applying the cathode mixture paste to the cathode current collector 31 and drying the paste. The cathode mixture layer 32 includes a conduction support, a binder, and an additive such as a dispersant or the like, in addition to the cathode active material particles.

### Composition of Cathode Active Material

The cathode active material particles contain a lithium transition metal oxide having a layered crystalline structure. The lithium transition metal oxide includes one or more predetermined transition metal elements, in addition to Li. Preferably, the transition metal element contained in the lithium transition metal oxide is at least one of Ni, Co, and Mn. The cathode active material of the present embodiment is, for example, of a ternary type, referred to as NCM, having a lithium transition metal oxide that includes all of Ni, Co, and Mn.

The cathode active material of the present embodiment is not limited to a lithium transition metal oxide that includes all of Ni, Co, and Mn. Alternatively, the lithium transition metal oxide may have a composition containing other types of elements, such as Al. Furthermore, the cathode active material may be LiMnO₄, LiFePO₄, or the like.

### Separator 4

The separator 4 is a non-woven fabric of polypropylene, which is a porous resin, or the like that has a superior insulation property and holds the non-aqueous electrolyte solution 13 between the anode plate 2 and the cathode plate 3. Alternatively, the separator 4 may be any one of or a combination of a porous polymer film (e.g., porous polyethylene film, porous polyolefin film, porous polyvinyl chloride film, or the like) and a lithium-ion-conductive or ion-conductive polymer electrolyte film.

### Overall Configuration of Vehicle Including Rechargeable Battery

FIG. 5 is a block diagram showing an example of the configuration of a vehicle to which the lithium-ion rechargeable battery 1 is applied. The vehicle shown in FIG. 5 is a hybrid electric vehicle. The vehicle includes the controller 18, a power control unit (PCU) 30, motor generators 41 and 42, an engine 50, a power splitter 60, a drive shaft 70, and driven wheels 80. The controller 18 also functions as a charge/discharge controller for the lithium-ion rechargeable battery 1. In the present embodiment, the controller 18 of the lithium-ion rechargeable battery 1 includes a battery module 1M, a monitoring unit 40, and an electronic control unit (ECU) 100.

The engine 50 is an internal combustion engine that outputs power by converting the energy produced by combustion of an air-fuel mixture into kinetic energy of a moving part, such as a piston or a rotor.

The power splitter 60 includes, for example, a planetary gear mechanism (not shown) having three rotary shafts; namely, a sun gear, a carrier, and a ring gear. The power splitter 60 divides the power output from the engine 50 into power that drives the motor generator 41 and power that drives the driven wheels 80.

Each of the motor generators 41 and 42 is an AC rotating electric machine, for example, a three-phase AC synchronous electric motor in which permanent magnets (not shown) are embedded in a rotor. The motor generator 41 is mainly used as a generator that is driven by the engine 50 via the power splitter 60. The electric power generated by the motor generator 41 is supplied via the PCU 30 to the motor generator 42 or the lithium-ion rechargeable battery 1.

The motor generator 42 operates mainly as an electric motor and drives the driven wheels 80. The motor generator 42 is driven by at least one of the electric power received from the lithium-ion rechargeable battery 1 and the electric power generated by the motor generator 41. Then, the driving force of the motor generator 42 is transmitted to the drive shaft 70. On the other hand, when the vehicle is braked or decelerating on a downhill slope, the motor generator 42 operates as a generator and performs regenerative braking. The electric power generated by the motor generator 42 is supplied via the PCU 30 to the battery module 1M.

The battery module 1M includes the lithium-ion rechargeable battery 1, which is formed by a plurality of battery cells. The lithium-ion rechargeable battery 1 stores electric power for driving the motor generators 41 and 42 and supplies the electric power via the PCU 30 to the motor generators 41 and 42. Also, when the motor generators 41 and 42 are generating electric power, the lithium-ion rechargeable battery 1 is charged with the electric power received from the PCU 30.

The monitoring unit 40 includes a voltage measurement device 40a, a current measurement device 40b, and a temperature measurement device 40c. The voltage measurement device 40a of the present embodiment detects, for example, a voltage E of each battery cell of the lithium-ion rechargeable battery 1. Alternatively, the voltage measurement device 40a may detect the voltage E of the entire battery module 1M, which includes multiple cells of the lithium-ion rechargeable battery 1 connected in parallel to one another. In this case, the voltage of each battery cell may be estimated from the total voltage. The current measurement device 40b detects a current I input to and output from the lithium-ion rechargeable battery 1. The temperature measurement device 40c detects a temperature T of each block. Each of these measurement devices outputs a signal indicating a corresponding detection result to the ECU 100.

Basically, the voltage measurement device 40a and the temperature measurement device 40c monitor each battery cell of the lithium-ion rechargeable battery 1. However, there is no limitation to such a configuration. The voltage measurement device 40a and the temperature measurement device 40c may monitor each block of the lithium-ion rechargeable battery 1.

The PCU 30 performs bidirectional power conversion between the lithium-ion rechargeable battery 1 and the motor generators 41 and 42 in accordance with a control signal from the ECU 100. The PCU 30 is configured to separately control the states of the motor generators 41 and 42. For example, the motor generator 42 may be shifted to a power running state while the motor generator 41 is in a regenerative state (power generation state). The PCU 30 is arranged, for example, in correspondence with the motor generators 41 and 42. The PCU 30 includes two inverters (not shown) and a converter (not shown) that increases a DC voltage supplied to each of the inverters to an output voltage or greater of the lithium-ion rechargeable battery 1.

### ECU 100

In the present embodiment, the ECU 100 of the controller 18 controls charging and discharging.

The ECU 100 includes a central processing unit (CPU) 101, the memory 102, and an input-output port (not shown) that receives and outputs various signals.

### Memory 102

The memory 102 includes a read only memory (ROM) and a random access memory (RAM). The memory 102 further includes, for example, a storage medium that stores programs and maps, such as an erasable programmable read only memory (EPROM), a solid state drive (SSD), a hard disk drive (HDD), or the like.

The ECU 100 controls charging and discharging of the lithium-ion rechargeable battery 1 by controlling the engine 50 and the PCU 30 in accordance with signals received from the measurement devices and programs and maps stored in the memory 102.

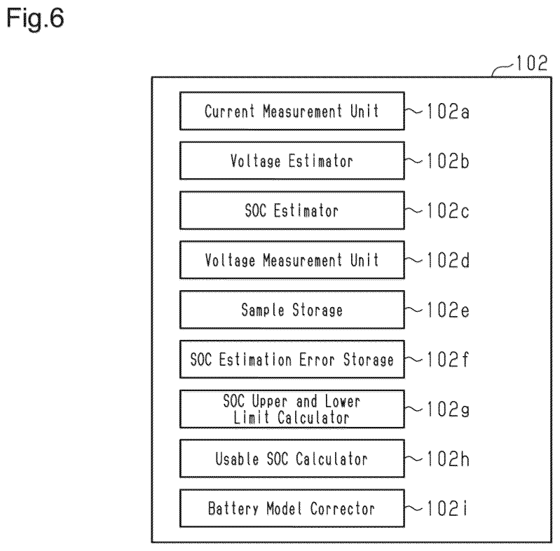

FIG. 6 is a block diagram showing some of the programs stored in the memory 102. As shown in FIG. 6, the memory 102 stores a program that causes the CPU 101 to act as a current measurement unit 102a. In the same manner, the memory 102 stores a voltage estimator 102b, an SOC estimator 102c, a voltage measurement unit 102d, sample storage 102e, SOC estimation error storage 102f, an SOC upper and lower limit calculator 102g, a usable SOC calculator 102h, and a battery model corrector 102i. The memory 102 may store programs for executing respective processes and corresponding results of the processes.

### Method for Controlling Charging and Discharging of Lithium-Ion Rechargeable Battery 1 of the Present Embodiment

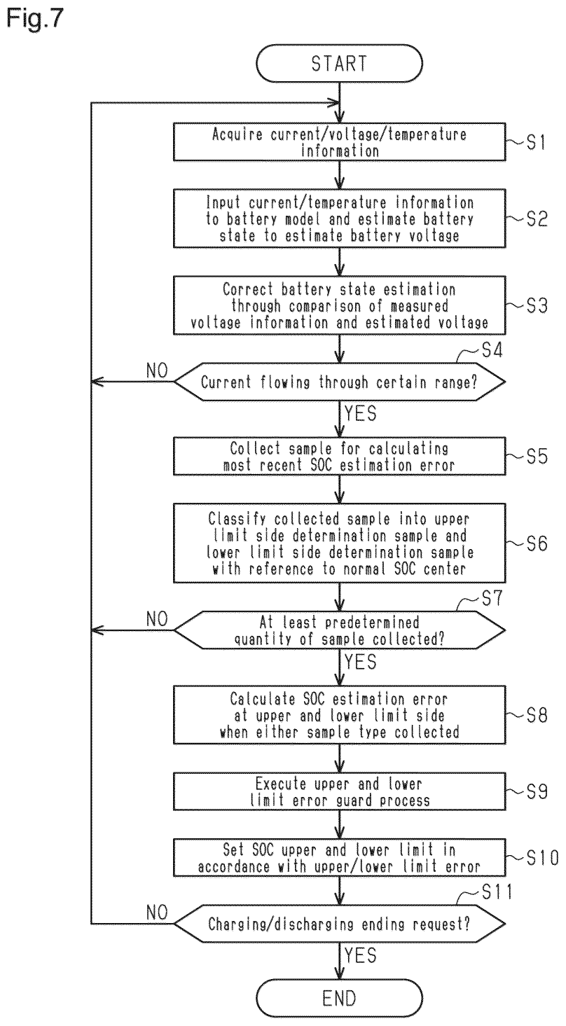

FIG. 7 is a flowchart illustrating a procedure of the method for controlling charging and discharging of the lithium-ion rechargeable battery 1 in accordance with the present embodiment. The method for controlling charging and discharging of the lithium-ion rechargeable battery 1 in accordance with the present embodiment will now be described with reference to the flowchart shown in FIG. 7.

First, control on the lithium-ion rechargeable battery 1 installed in the vehicle shown in FIG. 5 is initiated. Typically, the control is initiated when a lithium-ion rechargeable battery 1 having an unknown use history is installed. Alternatively, the control may be initiated when the method for controlling charging and discharging of the lithium-ion rechargeable battery 1 in accordance with the present embodiment is initially applied to a lithium-ion rechargeable battery 1 that is already installed.

### Obtaining Current/Voltage/Temperature Information (S1)

First, the current/voltage/temperature information is obtained (S1). The ECU 100 of the monitoring unit 40 shown in FIG. 5 obtains the current/voltage/temperature information of each battery cell by running the programs for the current measurement unit 102a, the voltage measurement unit 102d, and the SOC estimator 102c (measuring the temperature) stored in the memory 102.

The measured current A_{M} (A) is measured by the current measurement device 40b, the measured voltage V_{M} (V) is measured by the voltage measurement device 40a, and the measured temperature T_{M} (° C.) is measured by the temperature measurement device 40c. The measured values are stored in the memory 102. This procedure corresponds to the information acquisition step of the present embodiment.

### Inputting Current/Temperature Information to Battery Model to Estimate Battery State and Estimate Battery Voltage (S2)

Next, the current/temperature information is input to the battery model so as to estimate the battery state and estimate the battery voltage (S2). Specifically, the ECU 100 acts as the voltage estimator 102b and inputs the measured current A_{M} (A) and the measured temperature T_{M} (° C.) to the battery model shown in FIG. 2 so as to estimate the battery state and obtain the estimated voltage V_{E} (V). This procedure corresponds to the battery voltage estimation step of the present embodiment.

Correcting Battery State Estimation through Comparison of Measured Voltage Information and Estimated Battery (S3)

Next, the battery state estimation is corrected through comparison of the measured voltage information and the estimated voltage (S3). Specifically, the ECU 100 acts as the battery model corrector 102i and calculates the difference ΔV (V) between the measured voltage V_{M} (V) and the estimated voltage V_{E} (V). In this case, when the ECU 100 determines that the difference ΔV (V) is greater than a certain threshold value, the ECU 100 corrects the battery model as needed. This procedure corresponds to the battery model correction step of the present embodiment.

### Current Flowing Through Certain Range? (S4)

Next, whether the current is flowing through a certain range is determined (S4). Specifically, the ECU 100 runs the programs stored in the sample storage 102e and determines whether samples may be collected over a certain duration or at a certain current or higher (for example, under “certain condition” described above). This procedure corresponds to part of the sample collection step of the present embodiment. When the ECU 100 determines that the current is not flowing through the certain range (S4: NO), the ECU 100 returns to S1.

### Collecting Samples for Calculating Most Recent SOC Estimation Error (S5)

When the ECU 100 determines that the current is flowing through a certain range (S4: YES), the ECU 100 stores the sample SP in accordance with the program stored in the sample storage 102e. When the current value is less than a predetermined current value (A), or the duration is shorter than a predetermined duration (for example, less than one second), the ECU 100 does not collect a sample. Subsequently, the ECU 100 searches for data that is in conformance with the collecting condition. This procedure corresponds to part of the sample collection step of the present embodiment.

Classifying Collected Sample into Upper Limit Side Determination Sample and Lower Limit Side Determination Sample with Reference to Normal SOC Center (S6)

The collected sample is classified into the upper limit side determination sample and the lower limit side determination sample with reference to the normal SOC center (S6). In the present embodiment, when the sample indicates less than or equal to SOC 50%, the ECU 100 determines that the sample is for the lower limit side determination. When the sample indicates greater than SOC 50%, the ECU 100 determines that the sample is for upper limit side determination. The ECU 100 classifies and stores the sample in accordance with the program stored in the sample storage 102e. This procedure corresponds to the sample classification step of the present embodiment.

### At Least Predetermined Quantity of Sample Collected? (S7)

Next, the ECU 100 determines whether at least a predetermined quantity of samples are collected (S7). In the present embodiment, the term “predetermined” means, for example, that ten effective upper limit side determination samples SP_{H} and ten effective lower limit side determination samples SP_{L} are collected. Ten samples may sufficiently minimize the effects of noise or bias on the charging/discharging control.

Alternatively, until a predetermined quantity of one type of the upper limit side determination sample SP_{H} and the lower limit side determination sample SP_{L} are collected, the other sample type may be constantly updated by adding new samples and deleting old samples. When a predetermined quantity of neither sample type is collected (S7: NO), the ECU 100 returns to S1.

Calculating SOC Estimation Error at Upper and Lower Limit Side when Either Sample Type Collected (S8)

When a predetermined quantity of either sample type is collected, (S7: YES), the ECU 100 calculates the SOC estimation error at the upper and lower limit sides (S8). Alternatively, the SOC estimation error may be calculated when both sample types are collected. The ECU 100 calculates and stores the SOC estimation error in accordance with the program stored in the SOC estimation error storage 102f. This procedure corresponds to the SOC estimation error calculation step of the present embodiment.

### Executing Upper and Lower Limit Guard Process (S9)

The guard process of the upper and lower limit error is executed (S9). Specifically, the ECU 100 executes the process in accordance with the program stored in the SOC upper and lower limit calculator 102g. This process is executed only when necessary. Specifically, for example, the process may be executed when the corrected usable SOC range SUR (%) shown in FIG. 1 is less than 20%.

First, the ECU 100 calculates the SOC estimation error of the upper and lower limit sides (S8). Then, the ECU 100 limits the initially set usable SOC range S_{U0} (%) based on the upper limit error E_{H} (%) and the lower limit error E_{L} (%), which are the SOC estimation errors at the upper limit side and the lower limit side, by the amount corresponding to the upper limit error E_{H} and the lower limit error E_{L} (%). This determines the corrected usable SOC range SUR (%). In this case, the upper limit error E_{H} (%) and the lower limit error E_{L} (%) are limited to a certain range. This procedure corresponds to the guarding step of the present embodiment.

### Setting SOC Upper and Lower Limit Based on Upper/Lower Limit Error (S10)

The ECU 100 sets the SOC upper and lower limits based on the upper/lower limit errors (S10), which sets the corrected usable SOC range SUR (%). When the setting is completed, the ECU 100 executes the charging/discharging control on the lithium-ion rechargeable battery 1 based on the corrected usable SOC range SUR (%) in accordance with program stored in the usable SOC calculator 102h. This procedure corresponds to the SOC upper and lower limits resetting step of the present embodiment.

### Charging/Discharging Ending Request? (S11)

When ending of the charging/discharging is requested (S11: YES), such as when the vehicle is deactivated, the ECU 100 ends charging/discharging and terminates the method for controlling charging and discharging of the lithium-ion rechargeable battery 1 in accordance with the present embodiment. When such a charging/discharging ending request is not issued, (S11: NO), the ECU 100 returns to S1 and continues the process.

### Operation of the Present Embodiment

The method for controlling charging and discharging of the lithium-ion rechargeable battery 1 in accordance with the present embodiment shown in FIG. 7 is to correct the usable SOC range in accordance with the SOC estimation errors without requiring complicated procedures so that charging and discharging are controlled safely and efficiently.

First, the controller obtains the measured current A_{M} (A), the measured voltage V_{M} (V), and the measured temperature T_{M} (° C.) of the lithium-ion rechargeable battery 1 (S1) as the basis for the control, and estimates the estimated voltage V_{E} (V) (S2). Then, the controller collects samples for calculating the SOC estimation error E (%) (S5). The samples each indicate the difference ΔV (V) between the measured voltage V_{M} (V) and the estimated voltage V_{E} (V). The upper limit error E_{H} and the lower limit error E_{L} (%) are calculated from the difference between the measured voltage V_{M} (V) and the estimated voltage V_{E} (V) (S8). In this manner, such voltage values allow for accurate and prompt calculation of the upper limit error E_{H} (%) and the lower limit error E_{L} (%).

When necessary, the guard process is executed to control the upper limit error E_{H} and the lower limit error E_{L} (%). This guard process ensures a certain range of the SOC (%) within which charging and discharging are controlled.

The upper limit L_{H} of the usable SOC is reset in accordance with the upper limit error E_{H} (%), and the lower limit L_{L} of the usable SOC is reset in accordance with the lower limit error E_{L} (S10). Subsequently, charging and discharging of the lithium-ion rechargeable battery 1 is controlled based on the corrected usable SOC range. The method for controlling charging and discharging of the lithium-ion rechargeable battery 1 in accordance with the present embodiment having such a configuration protects the lithium-ion rechargeable battery 1 from overcharging and overdischarging in an effective manner. Furthermore, the method accurately estimates the SOC so that the state of the lithium-ion rechargeable battery 1 is determined accurately. This safely enhances the performance of the lithium-ion rechargeable battery 1.

### Advantages of the Present Embodiment

(1) The method for controlling charging and discharging of the lithium-ion rechargeable battery 1 according to the present embodiment corrects the usable range of the SOC in accordance with the SOC estimation error without requiring complicated procedures so that the charging and discharging are controlled safely and efficiently.

(2) In the present embodiment, the SOC estimation error calculation step calculates the upper limit error E_{H} (%) based on at least a predetermined quantity of the upper limit side determination samples SP_{H}, and calculates the lower limit error E_{L} (%) based on at least a predetermined quantity of the lower limit side determination samples Sp_{L}. This allows for accurate calculation of the upper limit error E_{H} (%) and the lower limit error E_{L} (%) of the SOC in real time.

(3) In the present embodiment, the SOC upper and lower limits resetting step resets the upper limit L_{H} of the usable SOC range in accordance with the upper limit error E_{H} (%), and resets the lower limit L_{L} of the usable SOC range in accordance with the lower limit error E_{L}. The upper and lower limits are reset separately. This optimizes the SOC range within which charging and discharging are controlled.

(4) When resetting the upper and lower limits based on the SOC estimation error E (%), the upper and lower limit guarding step of the present embodiment executes the guard process that optimizes the usable SOC range S_{U} to, for example, 20%. Thus, even when the calculated SOC estimation error E (%) is excessively large, the controller may perform charging and discharging within the appropriately guarded range. This ensures smooth operation of the vehicle.

(5) The battery voltage estimation step estimates the voltage V_{E} that corresponds to a closed circuit voltage of the lithium-ion rechargeable battery 1 as the estimated voltage. The voltage V_{E} is obtained from the preset battery model of the lithium-ion rechargeable battery 1. This allows for real-time calculation of the estimated voltage V_{E} (V).

(6) In the present embodiment, the battery model correction step corrects the battery model through comparison of the measured voltage V_{M} (V) and the estimated voltage V_{E} (V), when necessary. In this manner, the detected errors are incorporated into the correction of the battery model. This increases the degree of accuracy in detecting the SOC estimation error.

(7) The SOC estimation error E may be calculated in real time by using Equation 1. Accordingly, the estimation error of the lithium-ion rechargeable battery 1 may be calculated in real time.

(8) Even when the lithium-ion rechargeable battery 1 installed in the vehicle has a use history, the method for controlling the lithium-ion rechargeable battery 1 according to the present embodiment performs the charging/discharging control safely and efficiently in accordance with the deterioration state of the battery.

(9) The method for controlling the lithium-ion rechargeable battery 1 according to the present embodiment may be readily applied to a typical vehicle.

### Modified Examples

The present embodiment describes an example of a plate-shaped lithium-ion rechargeable battery 1 mounted on a vehicle. However, the lithium-ion rechargeable battery 1 may be installed in a marine vessel, an aircraft, or the like. The lithium-ion rechargeable battery 1 may be applied to a stationary battery used in a factory or a household. In addition, the lithium-ion rechargeable battery 1 may have any shape, such as a cylindrical shape.

The present embodiment describes the lithium-ion rechargeable battery 1 as an example of a rechargeable battery. However, there is no limitation to the battery type. The battery may be other types of non-aqueous electrolyte solution rechargeable battery, an alkaline rechargeable battery, such as a nickel-metal hydride battery (NiMH), a solid-state battery, or the like.

The battery model shown in FIG. 2 is used as an example of a simplified model. Alternatively, a more complex model may be used.

The present embodiment describes the lithium-ion rechargeable battery 1 as an example of a battery cell included in the battery module 1M, which is an assembled battery. However, the lithium-ion rechargeable battery 1 may be a single battery cell that is controlled independently. Alternatively, the lithium-ion rechargeable battery 1 may be a battery pack including a plurality of battery modules. In this case, the measurement current A_{M} (A) and the measurement voltage V_{M} (V) may be obtained directly from each battery cell or the assembled battery as a whole.

The present embodiment calculates the SOC estimation error using Equation 1. However, the SOC estimation error may be calculated by another method.

The present embodiment separately controls the upper and lower limits of the SOC range. However, the upper and lower limits may be processed together.

In the present embodiment, the initial usable SOC range S_{U0} is set to a range of 20% to 80%, inclusive. However, the initial usable SOC range S_{U0} may be less than 20% or greater than 80% in accordance with the properties of the battery.

The guard process sets the SOC range usable for the control to 20%. However, there is no limitation to such a configuration.

The numerical values and the numerical ranges in the present embodiment are merely examples. One skilled in the art may optimize such values and ranges in accordance with the properties of the battery. The quantity of the samples, the sample acquisition time, or the like are described above as examples, and may be optimized by one skilled in the art.

The flowchart shown in FIG. 7 is provided as an example for illustration of the present disclosure, and is not intended to limit the configuration. One skilled in the art may add, remove, replace, or modify the steps.

It should be apparent to one skilled in the art that the present disclosure may be embodied in many other specific forms without departing from the spirit or scope of the claims.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A method for controlling charging and discharging of a rechargeable battery with a controller, the method comprising:
acquiring a measured current A_{M} (A), a measured voltage V_{M} (V), and a measured temperature T_{M} (° C.) through measurement of the rechargeable battery;
estimating an estimated voltage V_{E} (V) based on the measured current A_{M} (A) and the measured temperature T_{M} (C);
collecting samples each indicating a difference ΔV (V) between the measured voltage V_{M} (V) and the estimated voltage E_{E} (V) for calculating an SOC estimation error E (%), the samples being collected when a current I is flowing through the rechargeable battery under a certain condition;
classifying the collected samples into an upper limit side determination sample SP_{H} and a lower limit side determination sample SP_{L} with reference to a reference value S (%) set at a preset normal SOC center;
calculating an upper limit error E_{H} (%), which is an estimation error E with respect to an upper limit L_{H} of a usable SOC range S_{U}, based on at least a predetermined quantity of the collected upper limit side determination sample SP_{H}, and calculating a lower limit error E_{L} (%), which is the estimation error E_{L} with respect to a lower limit L_{L} of the usable SOC range S_{U}, based on at least a predetermined quantity of the collected lower limit side determination sample SP_{L}; and
resetting the upper limit L_{H} of the usable SOC range S_{U} in accordance with the upper limit error E_{H} (%), and resetting the lower limit L_{L} of the usable SOC range S_{U} in accordance with the lower limit error E_{L} to control the usable SOC range S_{U} of the rechargeable battery.

2. The method according to claim 1, further comprising:
executing a guard process that optimizes the usable SOC range S_{U} based on the reset upper limit L_{H} and the reset lower limit L_{L} of the reset usable SOC range S_{U}.

3. The method according to claim 2, wherein the executing a guard process includes controlling resetting of the upper limit L_{H} and the lower limit L_{L} so that the usable SOC range S_{U} is greater than or equal to 20% based on the upper limit L_{H} and the lower limit L_{L}.

4. The method according to claim 3, wherein the executing a guard process includes setting the upper limit L_{H}, which is reset in accordance with the upper limit error E_{H}, in a range of a minimum difference ΔMin to a maximum difference ΔMax of the upper limit error E_{H}, and setting the lower limit L_{L}, which is reset in accordance with the lower limit error E_{L}, in a range of a minimum difference ΔMin to a maximum difference ΔMax of the lower limit error E_{L}.

5. The method according to claim 1, wherein the estimating an estimated voltage V_{E} (V) includes estimating a voltage V_{E} (V), which corresponds to a closed circuit voltage of the rechargeable battery, as the estimated voltage using a preset battery model of the rechargeable battery.

6. The method according to claim 5, further comprising:
correcting the battery model through comparison of the measured voltage V_{M} (V) and the estimated voltage V_{E} (V).

7. The method according to claim 6, wherein the correcting the battery model is performed when the difference ΔV (V) between the measured voltage V_{M} (V) and the estimated voltage V_{E} (V) becomes greater than or equal to a threshold value Th.

8. The method according to claim 1, wherein the classifying the collected samples includes setting the reference value S to a value in a range of SOC 40% to SOC 60%, inclusive, the reference value S being set at the preset normal SOC center for classifying the collected samples into the upper limit side determination sample and the lower limit side determination sample.

9. The method according to claim 1, wherein,
when the SOC estimation error is represented by E (%), a quantity of collected samples is represented by N, a number of sample collections executed is represented by k, the measured voltage is represented by V_{M} (V), the estimated voltage is represented by V_{E} (V), and a voltage corresponding to 1% of SOC of the rechargeable battery is represented by V₁ (V), the calculating an upper limit error E_{H} (%) and a lower limit error E_{L} (%) includes calculating the estimation error E (%) using Equation 1.
$$\begin{matrix}Expression 1 & \\ Estimation Error E = \frac{1}{N} {\sum }_{k = 1}^{N} ( \frac{\vert {V}_{M} - {V}_{E} \vert}{{V}_{1}} ) & Equation 1\end{matrix}$$

10. The method according to claim 1, wherein
the rechargeable battery serves as a driving power supply for a vehicle, and
the controller is mounted on the vehicle.

11. The method according to claim 1, wherein the rechargeable battery is a lithium-ion rechargeable battery.
